(19) United States
(12) Patent Application Publication
(10) Pub. No.: US 2014/0110461 A1
(43) Pub. Date: Apr. 24, 2014

(54) SYSTEM AND METHOD FOR CLEANING BOND WIRE

(71) Applicants: Mohd Rusli Ibrahim, Shah Alam (MY); Yin Kheng Au, Petaling Jaya (MY); Poh Leng Eu, Petaling Jaya (MY)

(72) Inventors: Mohd Rusli Ibrahim, Shah Alam (MY); Yin Kheng Au, Petaling Jaya (MY); Poh Leng Eu, Petaling Jaya (MY)

(21) Appl. No.: 13/716,193

(22) Filed: Dec. 16, 2012

(30) Foreign Application Priority Data
Oct. 24, 2012 (MY) PI2012004714

(51) Int. Cl. H01L 23/00; B23K 37/00

(52) U.S. Cl. CPC H01L 24/85; B23K 37/00; H01L 24/745
USPC 228/180.5; 228/4.5

(57) ABSTRACT

A system for cleaning bond wire for use by a wire bonding machine includes a bond wire supply station, a bond wire cleaning bath station, a bond wire neutralizing station, a bond wire drying station, and a wire bonding machine. In operation, the bonding machine is supplied with bond wire stored at the supply station, which is firstly de-oxidized with a cleaning solution in the cleaning bath station. Next, the cleaning solution on the bond wire is neutralized with a neutralizing liquid in the neutralizing station. The bond wire is then dried in the drying station. The speed of the bond wire passing through the cleaning bath station, neutralizing station and drying station is controlled by the wire bonding machine.

### BACKGROUND OF THE INVENTION

The present invention relates to assembly of semiconductor devices and, more particularly, to a system for de-oxidizing bond wire used for electrically connecting a semiconductor die to a lead frame or substrate during the semiconductor device assembly process.

Semiconductor devices are often formed with a semiconductor die mounted on a non-conductive substrate (die carrier). Bonding pads on the substrate are wire bonded, with a bond wire, to bonding pads on the die to provide a means of externally electrically connecting the die to circuit boards and the like. After the pads are wire bonded, the semiconductor die and die bond pads are encapsulated (packaged) in a compound such as a plastics material leaving external connectors of the substrate exposed for external electrical connection.

Wire bonding is a widely used technique for providing electrical connection between the semiconductor die and substrate. The integrity, or quality, of wire bond interconnections formed between the bonding pads of the semiconductor die and the bonding pads of the substrate is dependent on the condition of the bond wire. More specifically, the integrity, or quality, of wire bond interconnections is dependent on the bond wire being relatively free from oxidation.

Bond wire is typically a copper wire and when coated in an unwanted oxidized layer, the bond quality of the bond on the bonding pads of the substrate (known as the second bond) can be compromised and can also result in an absence of a bond wire tail for a first bond of the next bonding pad on the semiconductor die. Unfortunately, unwanted oxidized layers can form on copper bond wire in as little as 7 days. To improve the “shelf-life” of copper bond wire to around 30 to 40 days it is sometimes coated with Palladium. However, the Palladium coating can decrease the malleability of the copper bond wire, which can result in reduced wire bond quality, and can increase the cost of the wire by as much as four times.

Plasma cleaning is another technique used to remove oxidized layers on bond wires. Although useful, plasma cleaning is relatively expensive and does not necessarily remove sufficient amounts of oxidation unless the plasma cleaning process is allowed sufficient time to act on the bond wire. Accordingly, it would be advantageous to be able to increase the shelf-life of bond wire.

### BRIEF DESCRIPTION OF THE DRAWINGS

The invention, together with objects and advantages thereof, may best be understood by reference to the following description of preferred embodiments together with the accompanying drawings in which:

FIG. 1 is a schematic diagram of a system for cleaning bond wire for use by a wire bonding machine in accordance with a preferred embodiment of the present invention;

FIG. 2 is schematic diagram of another preferred embodiment of the bond wire neutralizing station forming part of the system of FIG. 1; and

FIG. 3 is a flow chart illustrating a method of cleaning a bond wire supplied from a bond wire supply station to a wire bonding machine in accordance with a preferred embodiment of the present invention.

### DETAILED DESCRIPTION OF PREFERRED EMBODIMENTS

The detailed description set forth below in connection with the appended drawings is intended as a description of presently preferred embodiments of the invention, and is not intended to represent the only forms in which the present invention may be practiced. It is to be understood that the same or equivalent functions may be accomplished by different embodiments that are intended to be encompassed within the spirit and scope of the invention. In the drawings, like numerals are used to indicate like elements throughout. Furthermore, terms “comprises,” “comprising,” or any other variation thereof, are intended to cover a non-exclusive inclusion, such that system, circuit, device components and method steps that comprises a list of elements or steps does not include only those elements but may include other elements or steps not expressly listed or inherent to such system, circuit, device components or steps. An element or step proceeded by “comprises . . . a” does not, without more constraints, preclude the existence of additional identical elements or steps that comprises the element or step.

In one embodiment of the present invention there is provided a system for cleaning bond wire for use by a wire bonding machine. The system includes a bond wire supply station, a bond wire cleaning bath station, a bond wire neutralizing station, a bond wire drying station, and a wire bonding machine. In operation, the bonding machine is supplied with bond wire stored at the supply station which is firstly de-oxidized with a cleaning solution in the cleaning bath station. Next, the cleaning solution on the bond wire is neutralized with a neutralizing liquid in the neutralizing station. The bond wire is then dried in the drying station. The speed of the bond wire passing through the cleaning bath station, neutralizing station and drying station is controlled by the wire bonding machine.

In another embodiment of the present invention there is provided a method of cleaning a bond wire supplied from a bond wire supply station to a wire bonding machine. The method includes de-oxidizing the bond wire, supplied from the supply station, in a cleaning bath station with a cleaning solution. Next the method performs neutralizing the cleaning solution on the bond wire with a neutralizing liquid and then drying the bond wire in the drying station to provide a de-oxidized bond wire. The de-oxidized bond wire is used in a wire bonding machine and the speed of de-oxidizing, neutralizing, and drying the bond wire is controlled by the wire bonding machine.

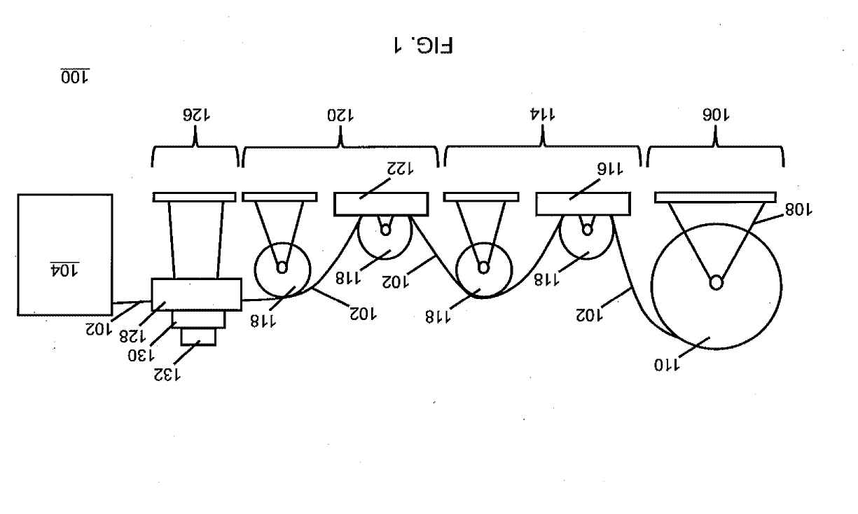

Referring to FIG. 1, a schematic diagram of a system 100 for cleaning bond wire 102 for use by a wire bonding machine 104 in accordance with a preferred embodiment of the present invention is shown. The system 100 has a bond wire supply station 106 that includes a spool mount 108 to allow a spool of bond wire 110 to be pivotally mounted a bout a pivot axis 112 to the spool mount 108. Proximal to the bond wire supply station 106 is a bond wire cleaning bath station 114 that includes a bath 116 containing a cleaning solution which is typically acid based. One such cleaning solution that may be used is sold by Air Products and Chemicals, Inc., under the product name BPS-729-A, which is typically used a surfactant dicing solution surface cleaner. The cleaning bath station 114 has pivotally mounted roller guides 118 or any other form of guides to direct the bond wire 102 into and out of the cleaning solution in the bath 116.

Proximal to the bond wire cleaning bath station 114 is a bond wire neutralizing station 120. In this embodiment the bond wire neutralizing station 120 includes a bath 122 of neutralizing liquid such as water (ideally distilled water. The neutralizing station 120 has pivotally mounted roller guides 124 or any other form of guides to direct the bond wire 102 into and out of the neutralizing liquid in the bath 122.

Next to the bond wire neutralizing station 120 is a bond wire drying station 128 that includes a drying chamber or tunnel 128. There is a fan 130 for blowing air onto the bond wire 102 and a heater 132 for heating the tunnel 128. The fan 130 in this embodiment is located in line with the heater 132 and therefore blows heated air into the tunnel 128 and onto the bond wire 102.

The wire bonding machine is 104 is located close to the bond wire drying station 128. In operation, the wire bonding machine 104 is supplied with the bond wire 102 stored at the supply station 106 which is firstly de-oxidized with the cleaning solution in the bath 116 of the cleaning bath station 114. After de-oxidizing the bond wire 102, the cleaning solution on the bond wire 102 is neutralized with the neutralizing liquid in the bath 122 of the neutralizing station 120. The bond wire is then dried in the drying station 126 and the speed of the bond wire 102 passing through the cleaning bath station 114, neutralizing station 120 and drying station 126 is controlled by the wire bonding machine. In this regard, the bond wire 102 is pulled through the system by the wire bonding machine 104. Also, if the wire bonding machine 104 stops bonding (due to for instance a fault of system configuration change), the roller guides 118 can move upwards to remove the bond wire 102 from the bath 116 so that the bond wire 102 is not over exposed to the cleaning solution.

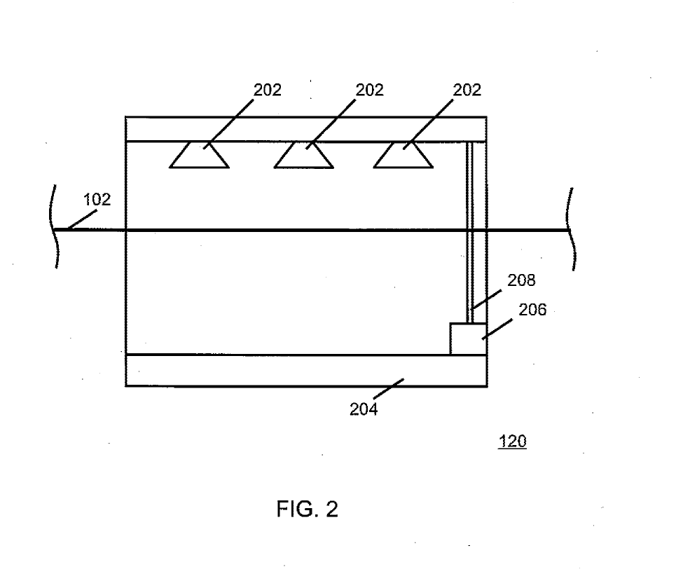

Referring to FIG. 2, a schematic diagram of another preferred embodiment of the bond wire neutralizing station 120 is shown. In this embodiment the bond wire neutralizing station 120 includes dispensing outlets in the form of sprinklers or shower heads 202 for dispensing the neutralizing liquid onto the bond wire 102. There is also a reservoir 204 for collecting the neutralizing liquid dispensed from the shower heads 202. A pump 206 and conduit 208 re-cycle the neutralizing liquid back to the shower heads 202. The pressure of the neutralizing liquid at the shower heads 202 can be controlled by the pump 206 in combination with pressure regulating valves (not shown) as will be apparent to a person skilled in the art.

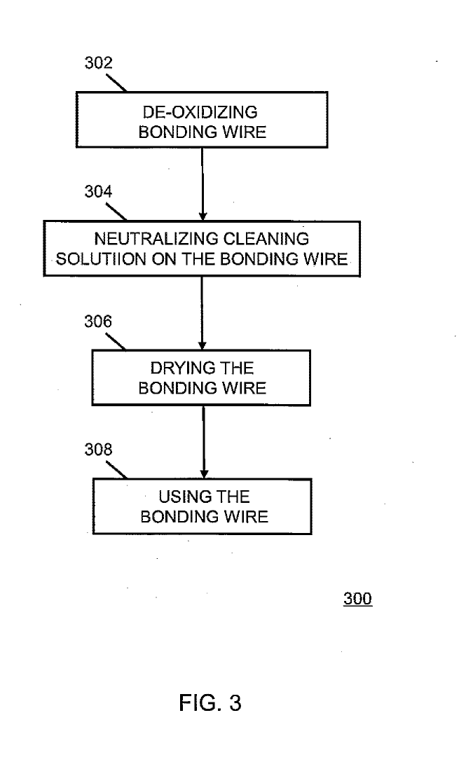

Referring to FIG. 3, a flow chart illustrating a method 300 of cleaning the bond wire 102 supplied from the bond wire supply station 106 to the wire bonding machine 104 in accordance with a preferred embodiment of the present invention is shown. The method 300, at a de-oxidizing block 302 performs de-oxidizing the bond wire 102. The bond wire 102 is supplied from the supply station 106 and is de-oxidized in the cleaning bath station 114 with the cleaning solution. Next, at a neutralizing block 304, the method 300 performs neutralizing the cleaning solution on the bond wire 102 with the neutralizing liquid. At a drying block 306, the bond wire 102 is dried in the drying station 126 to provide a de-oxidized and dried bond wire 102.

The de-oxidized bond wire 102 is used, at a using block 308, in the wire bonding machine 104 and the speed of de-oxidizing, neutralizing, and drying the bond wire is controlled by the wire bonding machine 104. The wherein bond wire is supplied from the supply station 106 by spooling, and the speed of spooling is controlled by the wire bonding machine which pulls the bond wire 102 through the system 100. Simple speed control of the system 100 is provided by the wire bonding machine 104 pulling the bond wire 102 and typically the use of the de-oxidized bond wire in the wire bonding machine 104 is within thirty minutes after the process of de-oxidizing the bond wire 102. This time may be significantly shorter and depends on the speed of the bonding machine 104 and length of the system 100.

Advantageously the present invention provides for cleaning, specifically de-oxidizing bond wire just before (typically within 30 minutes) it is used by the bonding machine 104. The bond wire 102 is typically copper wire that has an undesirable coating of copper oxide. Since the bond wire 102 when used is substantially free from a copper oxide coating, there is no need to pre-coat the wire with a protective coating such as Palladium and therefore one or more of the abovementioned problems are at least alleviated.

The description of the preferred embodiments of the present invention has been presented for purposes of illustration and description, but is not intended to be exhaustive or to limit the invention to the forms disclosed. It will be appreciated by those skilled in the art that changes could be made to the embodiments described above without departing from the broad inventive concept thereof. It is understood, therefore, that this invention is not limited to the particular embodiment disclosed, but covers modifications within the spirit and scope of the present invention as defined by the appended claims.

1. A system for cleaning bond wire for use by a wire bonding machine, the system comprising:
a bond wire supply station;
a bond wire cleaning bath station;
a bond wire neutralizing station;
a bond wire drying station; and
a wire bonding machine,
wherein in operation the cleaning bath station is supplied with bond wire stored at the supply station that is firstly de-oxidized with a cleaning solution in the cleaning bath station and then the cleaning solution on the bond wire is neutralized with a neutralizing liquid in the neutralizing station and then the bond wire is dried in the drying station,
wherein the speed of the bond wire passing through the cleaning bath station, neutralizing station and drying station is controlled by the wire bonding machine, and
wherein the neutralizing station includes dispensing outlets for dispensing the neutralizing liquid onto the bond wire, a reservoir for collecting the neutralizing liquid dispensed from the dispensing outlets, and a pump and conduit for re-cycling the neutralizing liquid back to the dispensing outlets.

2. (canceled)

3. The system of claim 1, wherein the neutralizing liquid is water.

4. (canceled)

5. (canceled)

6. The system of claim 1, wherein the drying station includes at least one fan for blowing air onto the bond wire.

7. The system of claim 6, wherein the drying station includes a heater.

8. The system of claim 1, wherein the wire supply station includes a spool mount to allow a spool of bond wire to be pivotally mounted thereto.

9. The system of claim 1, wherein cleaning solution in the cleaning bath station is an acid based liquid solution.

10. The system of claim 1, wherein in operation the bond wire is used by the bonding machine within thirty minutes after being de-oxidized in the cleaning bath station.

11. A method of cleaning a bond wire supplied from a bond wire supply station to a wire bonding machine, the method comprising:
de-oxidizing the bond wire, supplied from the supply station, in a cleaning bath station with a cleaning solution;
neutralizing the cleaning solution on the bond wire by dispensing a neutralizing liquid onto the bond wire with dispensing outlets, wherein the neutralizing liquid dispensed from the dispensing outlets is collected by a reservoir and re-cycled back to the dispensing outlets by a pump and conduit;
drying the bond wire in the drying station to provide a de-oxidized bond wire; and
using the de-oxidized bond wire in a wire bonding machine, wherein the speed of de-oxidizing, neutralizing, and drying the bond wire is controlled by the wire bonding machine.

12. (canceled)

13. The method of cleaning a bond wire of claim 12, wherein the neutralizing liquid is water.

14. (canceled)

15. (canceled)

16. The method of cleaning a bond wire of claim 11, wherein the drying includes blowing air onto the bond wire.

17. The method of cleaning a bond wire of claim 16, wherein the air is heated.

18. The method of cleaning a bond wire of claim 11, wherein bond wire is supplied from the supply station by spooling, and the speed of spooling is controlled by the wire bonding machine.

19. The method of cleaning a bond wire of claim 11, wherein the cleaning solution is an acid based liquid solution.

20. The method of cleaning a bond wire of claim 11, wherein the using the de-oxidized bond wire in the wire bonding machine is within thirty minutes after the process of de-oxidizing the bond wire.
